(19) United States
(12) Patent Application Publication
(10) Pub. No.: US 2008/0121892 A1
(43) Pub. Date: May 29, 2008

(54) Low temperature poly silicon liquid crystal display

(75) Inventors: Chang-Ho Tseng, Sinwu Township (TW); Shih-Pin Wang, Pingtung City (TW); Chun-Yen Liu, Jhubei City (TW); Kuo-Bin Hsu, Lugang Township (TW)

Correspondence Address: LIU & LIU, 444 S. FLOWER STREET, SUITE 1750, LOS ANGELES, CA, 90071, US

(73) Assignee: TPO Displays Corp.

(21) Appl. No.: 11/606,841

(22) Filed: Nov. 29, 2006

(51) Int. Cl. H01L 29/04; H01L 21/336

(52) U.S. Cl. 257/72; 438/151; 257/E29.003; 257/E21.413

(57) ABSTRACT

The invention discloses an LTPS LCD comprising a plurality of NMOS elements and PMOS elements on a substrate. Each element comprises a SiNₓ layer underlying or capping a gate electrode. The SiNₓ layer features an appropriate length extending from the bottom edge of the gate electrode. The SiNₓ layer can be replaced with a SiOₓN_{y} layer.

### BACKGROUND OF THE INVENTION

1. Field of the Invention

The present invention relates to a flat panel display, and in particular relates to a low temperature polysilicon thin film transistor liquid crystal display (LTPS TFT-LCD).

2. Description of the Related Art

In conventional fabrication processes for an LTPS LCD, switching elements are typically treated with an high pressure anneal (HPA) process to improve uniformity thereof. However, existing devices suffers from problems such as so-called “threshold voltage shift” (as shown in FIG. 3B) for a P-type thin film transistor (also PTFT) after the HPA treatment. Simultaneously, an N-type thin film transistor (also NTFT) can not be turned off normally, referring to FIG. 3A. As a result, an electric circuit of a panel may not work. Also, remaining oxide charges, possibly induced by the HPA treatment, may diffuse into active regions of the device.

Accordingly, an LTPS TFT-LCD capable of preventing such problems is desirable.

### BRIEF SUMMARY OF THE INVENTION

In view of the problems in related art, several embodiments are disclosed as the following.

One embodiment of a system for displaying images comprising: a low temperature poly-silicon liquid crystal display panel which comprises a substrate; an active layer, overlying the substrate; a gate insulating layer comprising a first extended portion, a second extended portion and a central portion therebetween, overlying the active layer; and a gate electrode, overlying the central portion of the gate insulating layer, wherein the active layer, the gate insulating layer and the gate electrode constitute a switching element; wherein the first extended portion and the second extended portion are uncovered by the gate electrode, and wherein each of the first extended portion and the second extended portion has a length larger than about 0.5 μm to prevent oxide charges from diffusing into the active layer.

Another embodiment of a system for displaying images comprising: a low temperature poly-silicon liquid crystal display panel which comprises a substrate; an active layer, overlying the substrate; a gate insulating layer, overlying the active layer; a., overlying the gate insulating layer; a gate electrode opposite to the active layer, overlying the gate insulating layer, wherein the active layer, the gate insulating layer and the gate electrode constitute a switching element; and a passivation layer comprises a first extended portion, a central portion covering the gate electrode and a second extended portion, wherein the first and second extended portions are in contact with the gate insulating layer, and wherein each of the first and second extended portions has a length larger than about 0.5 μm to prevent oxide charges from diffusing into the active layer.

Another embodiment of fabricating such a system for displaying images is also provided. The method comprise providing a low temperature poly-silicon thin film transistor, comprising: providing a substrate; forming an active layer overlying the substrate; forming a gate insulating layer overlying the active layer; forming a dielectric layer with a first extended portion, a second extended portion and a first central portion therebetween, overlying the gate insulating layer; and forming a gate electrode, overlying the central portion of the dielectric layer; and performing an HPA process on the low temperature poly-silicon thin film transistor.

According to embodiments of the invention, oxide charges induced by the subsequent HPA process are prevented from diffusing into switching elements by the extended SiNₓ layer or SiOₓN_{y} layer underlying or capping a gate electrode. As a result, uniformity of switching elements is enhanced such that electric circuits of a display can be operated normally.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1L are cross sections of one embodiment of a method of fabricating an LTPS LCD in accordance with the invention.

FIGS. 2A to 2F are cross sections of another embodiment of a method of fabricating an LTPS LCD in accordance with the invention.

FIGS. 3A to 3B are schematic diagrams of drain current vs. gate voltage for NMOS elements and PMOS elements of a conventional LTPS LCD, respectively.

FIGS. 4A to 4B are schematic diagrams of drain current vs. gate voltage for NMOS elements and PMOS elements of a LTPS LCD according to one embodiment of the invention, respectively.

FIGS. 5A to 5B are schematic diagrams of drain current vs. gate voltage for NMOS elements and PMOS elements of a LTPS LCD according to another embodiment of the invention, respectively.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

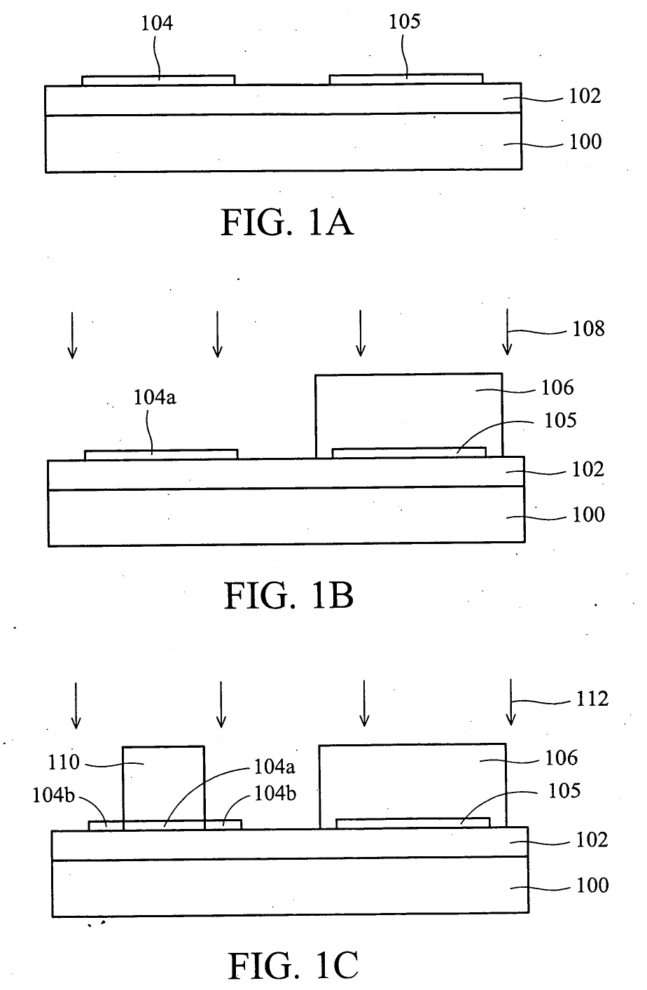

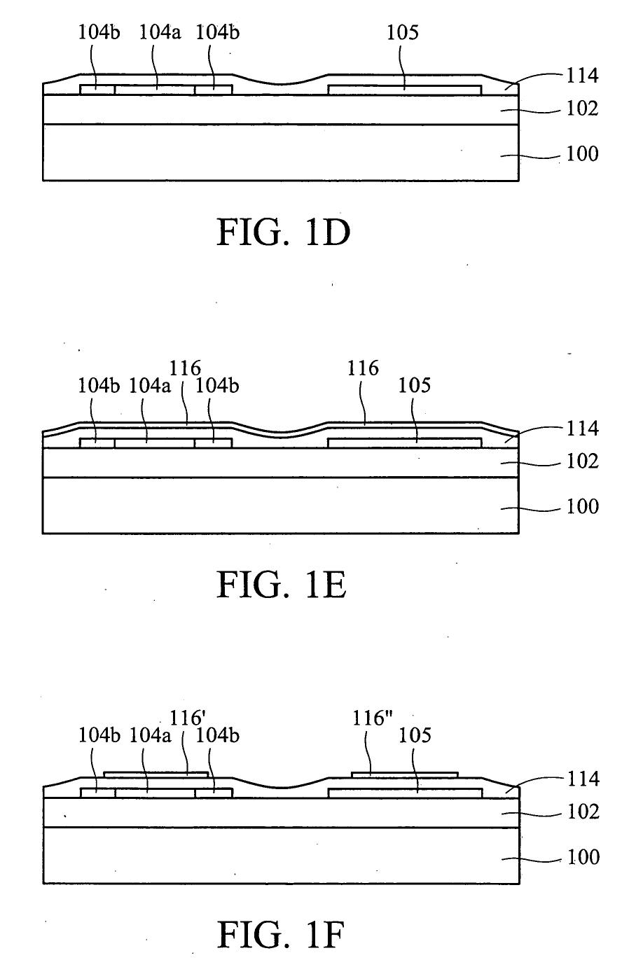

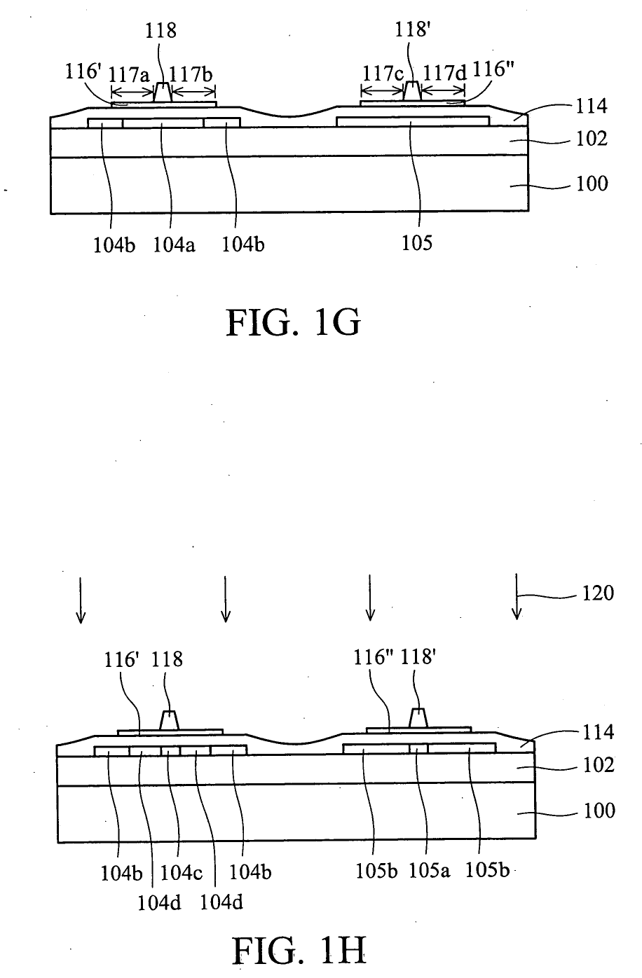

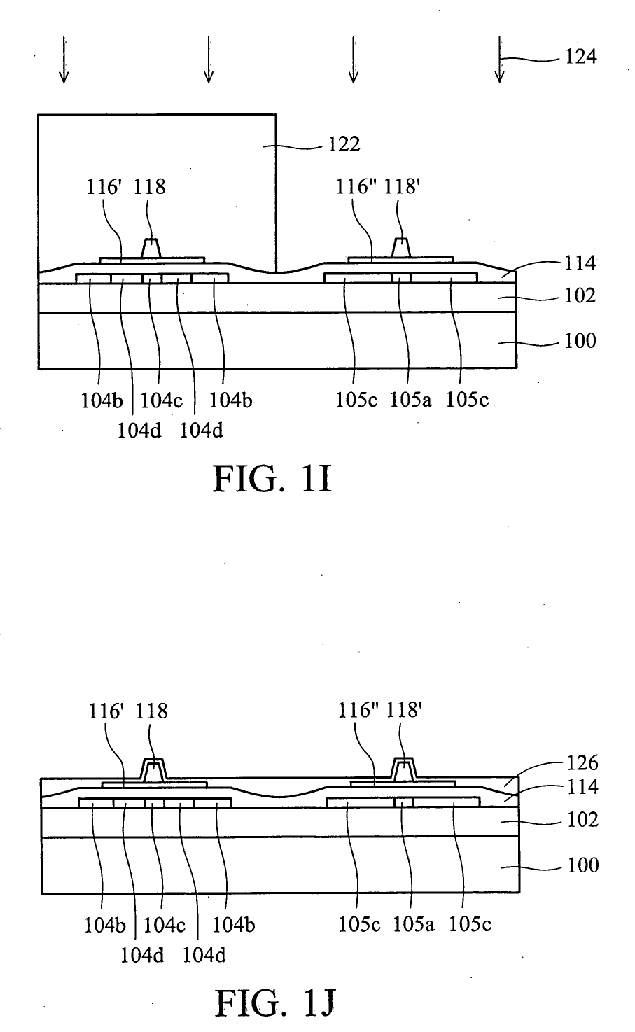

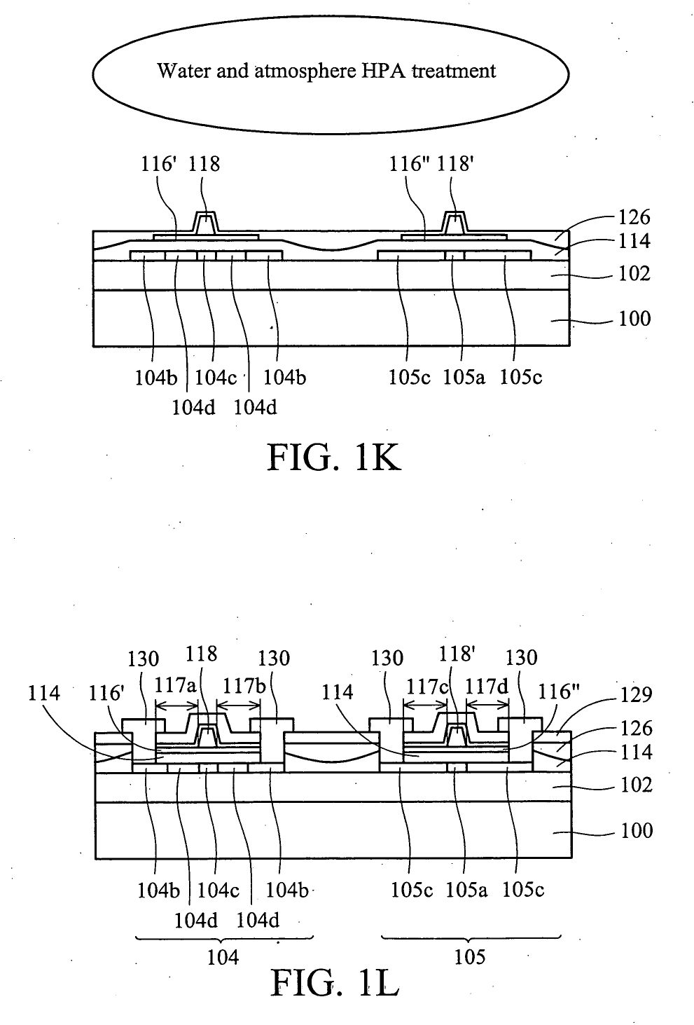

In a first embodiment of an LTPS LCD shown in FIG. 1L, a buffer layer 102 is on the substrate 100. An active layer layer is on the buffer layer 102, and comprises at least a first active layer including channel region 104c, LDDs 104d, source/drain electrodes 104b or a second active layer including channel region 105a, source/drain electrodes 105c, or both. A gate insulating layer 114 is on the active layer layer and the buffer layer 102. A dielectric layer layer is on the gate insulating layer 114, and comprises at least a first dielectric layer 116′ or a second dielectric layer 116″, or both. A first gate electrode 118 and a second gate electrode 118′ are on the first dielectric layer 116′ and the second dielectric layer 116″, respectively. An interlayer dielectric layer 126 is on the first gate electrode 118, the second gate electrode 118′, the dielectric layer layer, and, the gate insulating layer 114. A passivation layer 129 is on the interlayer dielectric layer 126. The first active layer, the gate insulating layer 114, the first dielectric layer 116′, and the first gate electrode 118 constitute an NMOS element. The second active layer, the gate insulating layer 114, the second dielectric layer 116′, and the second gate electrode 118′ constitute a PMOS element. Each conductive line 130 is in contact with the source/drain electrodes 104b of the NMOS element and the source/drain electrodes 105c of the PMOS element, respectively, through the passivation layer 129, the interlayer dielectric layer 126 and the gate insulating layer 114.

In addition, the first dielectric layer 116′ includes a first extended portion 117a and a second extended portion 117b which are not covered by the first gate electrode 118, each extended portion has a length large than 0.5 μm. The second dielectric layer 116″ includes a third extended portion 117c and a fourth extended portion 117d which are not covered by the second gate electrode 118′, each extended portion has a length large than 0.5 μm. The dielectric layer layer can be a SiNₓ layer or a SiOₓN_{y} layer. The length of the first extended portion 117a can equals that of the second extended portion 117b while the length of the first extended portion 117a may be not equal to that of the second extended portion 117b in other embodiments. Also, the length of the third extended portion 117c can equals that of the fourth extended portion 117d while the length of the third extended portion 117c may be not equal to that of the fourth extended portion 117d in other embodiments.

Processes of fabricating such an LTPS LCD are briefly described with accompanying drawings, FIGS. 1A to 1L. In FIG. 1A, a substrate 100 with a buffer layer 102 thereon is provided. An active layer, such as a poly silicon layer, is formed on the buffer layer 102. The active layer includes a first active layer 104 and a second active layer 105.

FIG. 1B, the second active layer 105 is covered by a photoresist material 106. A channel doping process 108 is conducted on the first active layer 104.

In FIG. 1C, the doped first active layer 104a is partially covered by a photoresist material 110, and the exposed portion of the doped first active layer 104a is subjected to an N+ doping process 112. Source/drain electrodes 104b are thus available. Subsequently, the photoresist material 106 and 110 are removed.

In FIG. 1D, a gate insulating layer 114 is formed on the first active layer 104, the second active layer 105, and the buffer layer 102.

In FIG. 1E, a dielectric material 116 is deposited on the gate insulating layer 114. After a conventional patterning process, a patterned dielectric layer including a first dielectric layer 116′ and a second dielectric layer 116″ is obtained, as shown in FIG. 1F. Specifically, each dielectric layer is extended to a desired length.

In FIG. 1G, the first, second gate electrodes 118, 118′ are formed on the first dielectric layer 116′ and the second dielectric layer 116″, respectively. It is noted that the first dielectric layer 116′ includes a first extended portion 117a and a second extended portion 117b; the second dielectric layer 116″ includes a third extended portion 117c and a fourth extended portion 117d.

In FIG. 1H, an LDD doping process 120 is performed, thus, a channel region 104c and LDDs 104d are formed. In FIG. 1I, the first gate electrode 118, the first dielectric layer 116′ and the first active layer 104 are covered by a photoresist material. A P+ doping process is conducted on the second active layer 105, forming source/drain electrodes 105c.

In FIG. 1J, an interlayer dielectric layer 126 is formed on the first gate electrode 118, the first dielectric layer 116′, the second gate electrode 118′, the second dielectric layer 116″, and the gate insulating layer 114.

In FIG. 1K, a water atmosphere HPA treatment followed by the formation of a capping layer is performed. Other well known processes such as metallization are subsequently progressed, as shown in FIG. 1L.

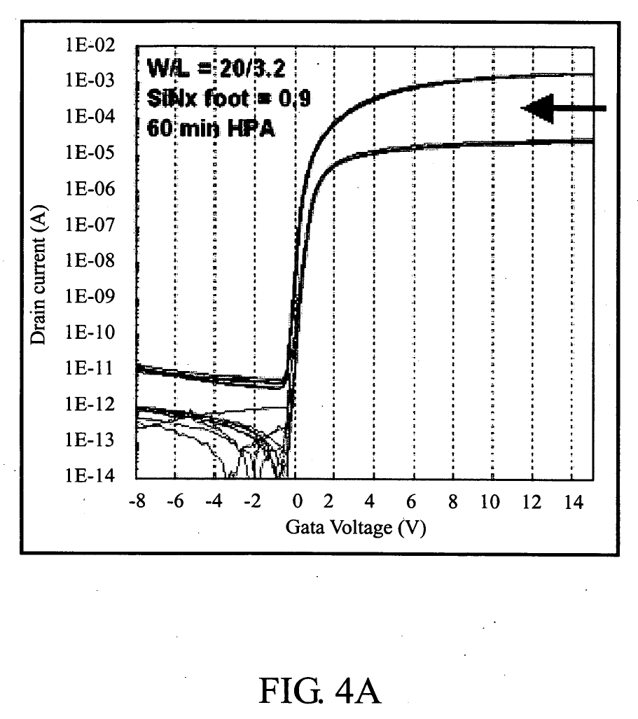

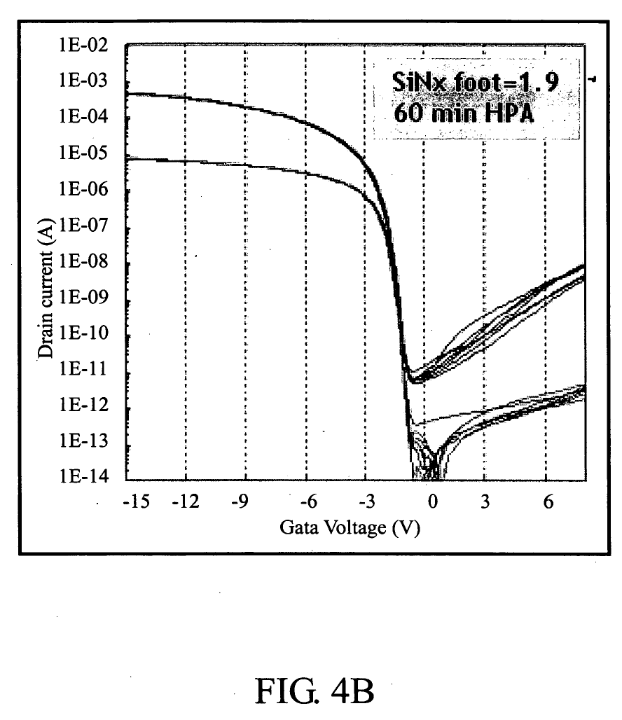

According to the first embodiment, oxide charges induced by the HPA process are prevented from diffusing into active layer by the extended SiNₓ layer or SiOₓN_{y} layer underlying a gate electrode. As a result, uniformity of switching elements is enhanced, as shown in FIGS. 4A and 4B for NMOS elements and PMOS elements, respectively, so that electric circuits of a display can be operated normally.

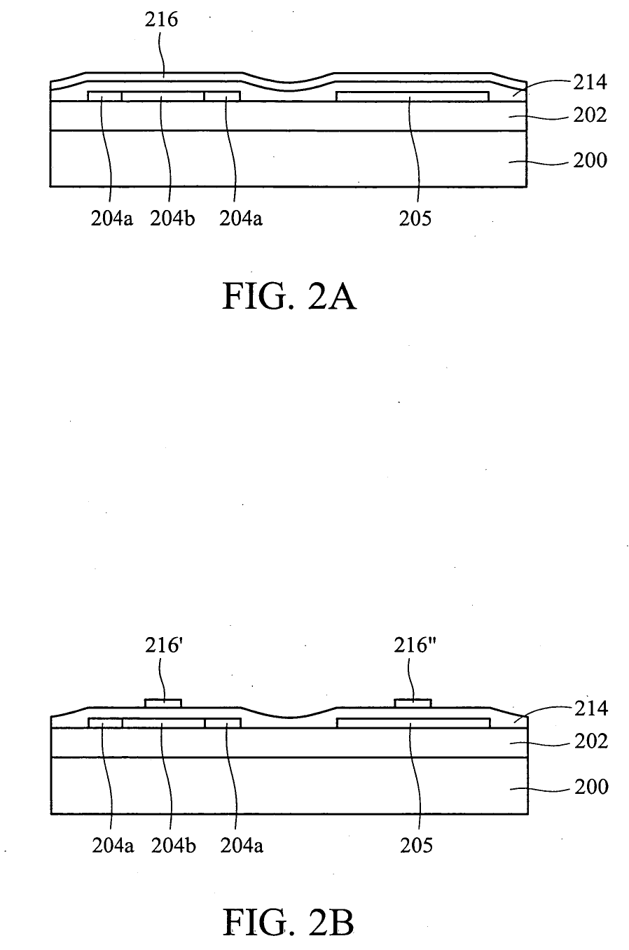

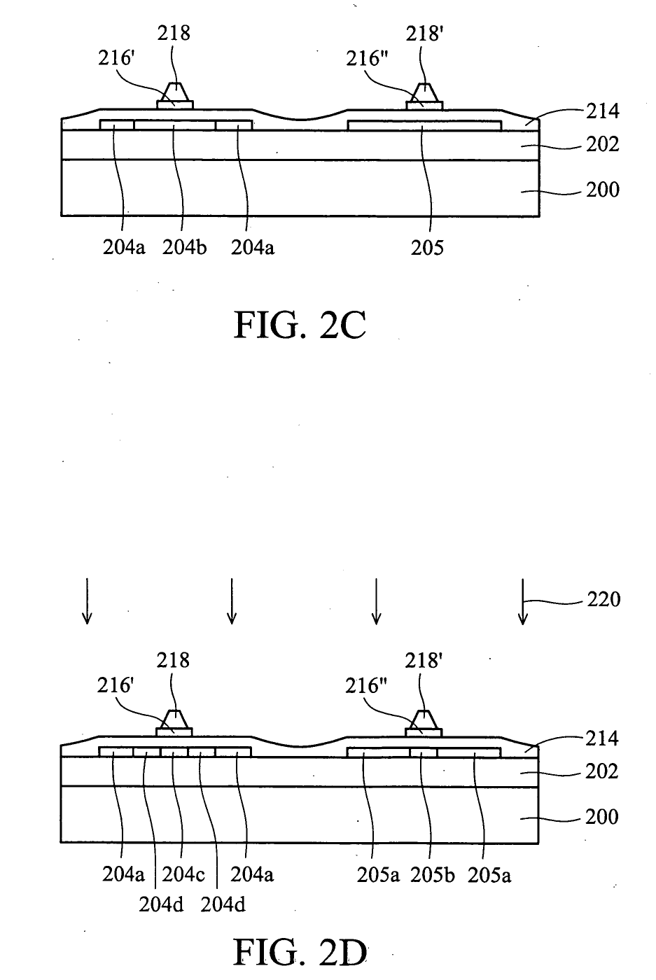

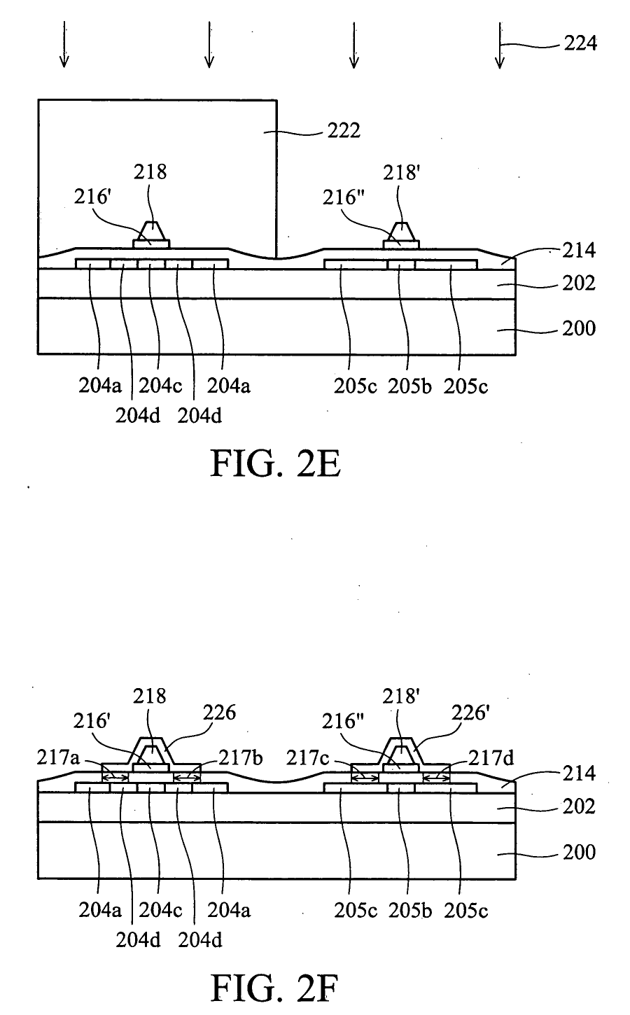

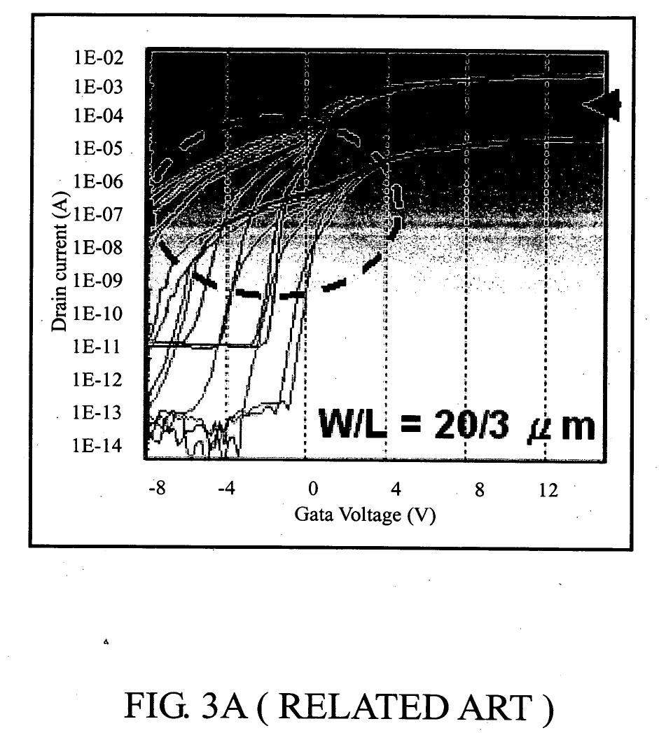

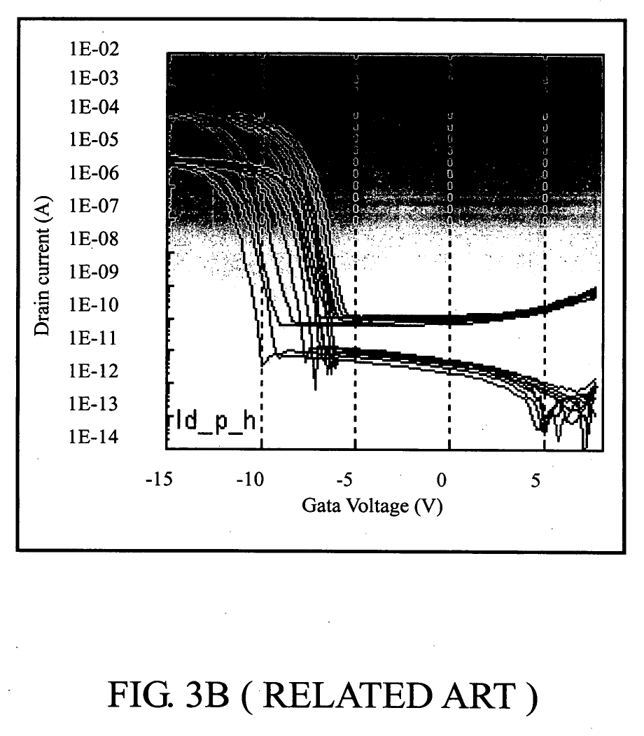

In a second embodiment of an LTPS LCD shown in FIG. 2F, a buffer layer 202 is on the substrate 200. An active layer layer is on the buffer layer 202, and comprises at least a first active layer including channel region, LDDs 204d, source/drain electrodes 204a or a second active layer including channel region 205b, source/drain electrodes 205c, or both. A gate insulating layer 214 is on the patterned active layer and the buffer layer 202. A patterned dielectric layer is on the gate insulating layer 214, and comprises at least a first dielectric layer 216′ or a second dielectric layer 216″, or both. A first gate electrode 218 and a second gate electrode 218′ are on the first dielectric layer 216′ and the second dielectric layer 216″, respectively. A first patterned passivation layer is on the first gate electrode 218, the second gate electrode 218′, the patterned dielectric layer, and the gate insulating layer 214, and it comprises a first passivation layer 226 and a second passivation layer 226′ which overly the first gate electrode 218 and the second gate electrode 218′, respectively. An interlayer dielectric layer (not shown) is on the first patterned passivation layer, the patterned dielectric layer, and the gate insulating layer 214. A capping layer (not shown) is on the interlayer dielectric layer. The first active layer, the gate insulating layer 214, the first dielectric layer 216′, and the first gate electrode 218 constitute an NMOS element. The second active pattern, the gate insulating layer 214, and the second dielectric pattern 216″, and the second gate electrode 218′ constitute a PMOS element. Similarly, each conductive line (not shown) is in contact with the source/drain electrodes 204a of the NMOS element and the source/drain electrodes 205c of the PMOS element, respectively, through the passivation layer, the interlayer dielectric layer and the gate insulating layer.

Specifically, the first passivation layer 226 includes a first extended portion 217a and a second extended portion 217b which are in contact with the first dielectric layer 216′ and the gate insulating layer 214, each extended portion has a length large than 0.5 μm. The second passivation layer 226′ includes a third extended portion 217c and a fourth extended portion 217d which are in contact with the second dielectric layer 216″ and the gate insulating layer 214, each extended portion has a length large than 0.5 μm. The first passivation layer 226 can be a SiNₓ layer or a SiOₓN_{y} layer. The length of the first extended portion 217a can equals that of the second extended portion 217b while the length of the first extended portion 217a may be not equal to that of the second extended portion 217b in other embodiments. Also, the length of the third extended portion 217c can equals that of the fourth extended portion 217d while the length of the third extended portion 217c may be not equal to that of the fourth extended portion 217d in other embodiments.

Fabrication processes of the second embodiment are similar to the first embodiment. An additional patterned passivation layer is formed.

In FIG. 2A, a buffer layer 202, a patterned active layer, a gate insulating layer 214 and a dielectric material 216 is formed on a substrate 200 in sequence. The patterned active layer includes a second active pattern 205 and a first active pattern comprising a doped region 204b, source/drain electrodes 204a.

In FIG. 2B, a patterned dielectric layer including a first dielectric layer 216′ and a second dielectric layer 216″ is formed after exposure and development processes. In FIG. 2C, gate electrodes 218 and 218′ are formed on the first dielectric layer 216′ and the second dielectric layer 216″, respectively. In FIG. 2D, an LDD doping process 220 is performed, forming LDDs 204d.

In FIG. 2E, the first gate electrode 218, the first dielectric layer 216′ and portions of the gate insulating layer 214 are covered by a photoresist material 222. Subsequently, a P+ doping process 224 is performed, and then the photoresist material 222 is removed.

In FIG. 2F, a patterned passivation layer comprising a first passivation layer 226 and a second passivation layer 226′ which respectively overly the first gate electrode 218 and the second gate electrode 218′ is formed. The subsequent processes such as the formation of a capping layer and metallization are well known.

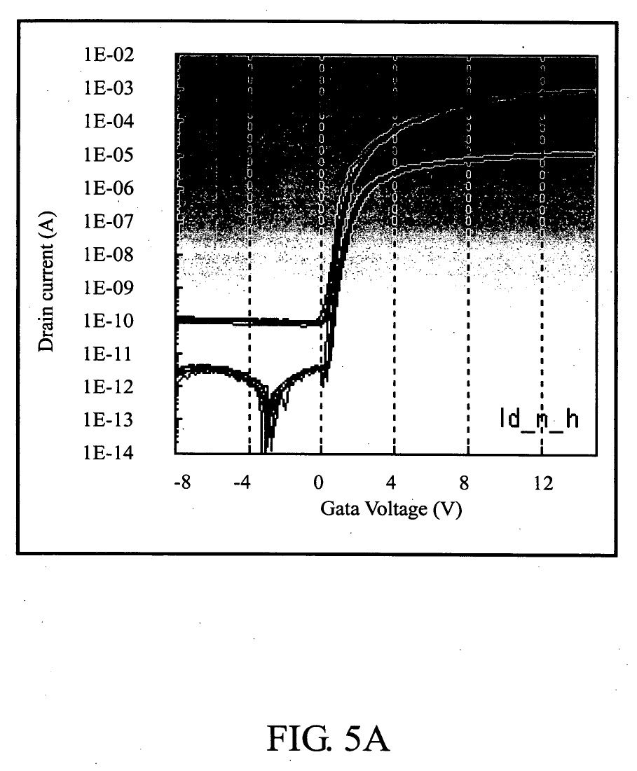

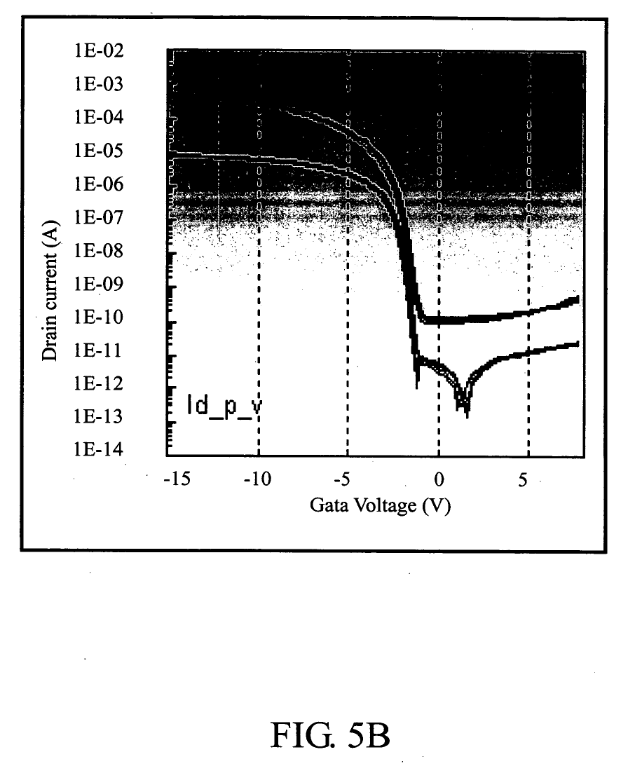

According to the second embodiment, oxide charges induced by the HPA process are prevented from diffusing into switching elements by the extended SiNₓ layer or SiOₓN_{y} layer capping a gate electrode. As a result, uniformity of switching elements is enhanced, as shown in FIGS. 5A and 5B for NMOS elements and PMOS elements, respectively, so that electric circuits of a display can be operated normally.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images comprising:
a low temperature poly-silicon thin film transistor comprising:
a substrate;
an active layer, overlying the substrate;
a gate insulating layer, overlying the active layer;
a dielectric layer comprising a first extended portion, a second extended portion and a first central portion therebetween, overlying the gate insulating layer; and
a gate electrode, overlying the first central portion of the dielectric layer.

2. The system as claimed in claim 1, further comprising:
a passivation layer overlying the gate electrode,comprising a third extended portion, a second central portion covering the gate electrode and a fourth extended portion, wherein the third and fourth extended portions are in contact with the gate insulating layer.

3. The system as claimed in claim 2, wherein the first extended portion and the second extended portion are uncovered by the gate electrode, and wherein each of the first extended portion and the second extended portion has a length larger than about 0.5 μm.

4. The system as claimed in claim 2, wherein each of the third extended portion and the fourth extended portion has a length larger than about 0.5 μm.

5. The system as claimed in claim 2, wherein the active layer is formed by converting an original amorphous silicon layer into a poly-silicon layer via laser crystallization or excimer laser annealing (ELA) anneal treatment.

6. The system as claimed in claim 2, the active layer, the gate insulating layer, the central portion of the dielectric layer and the gate electrode constitute a switching element, wherein the switching element is an NTFT and the active layer comprises LDD regions and source/drain regions.

7. The system as claimed in claim 2, the active layer, the gate insulating layer, the central portion of the dielectric layer and the gate electrode constitute a switching element, wherein the switching element is a PTFT and the active layer comprises source/drain regions.

8. The system as claimed in claim 2, further comprising:
a display panel, comprising : the low temperature poly-silicon thin film transistor; and
a controller coupled to the display panel, being operative to control the display panel to render images in accordance with input.

9. The system as claimed in claim 8, wherein the system comprises an electronic device comprising the display panel.

10. The system as claimed in claim 9, wherein the electronic device is a laptop computer, a mobile phone, a digital camera, a personal digital assistant (PDA), a desktop computer, a television, a car display or a portable. DVD player.

11. The system as claimed in claim 1, wherein the dielectric layer comprises silicon nitride or silicon oxynitride.

12. The system as claimed in claim 2, wherein the passivation layer comprises silicon nitride or silicon oxynitride.

13. A method of fabricating a system for displaying images, comprising:
providing a low temperature poly-silicon thin film transistor, comprising:
providing a substrate;
forming an active layer overlying the substrate;
forming a gate insulating layer overlying the active layer;
forming a dielectric layer with a first extended portion, a second extended portion and a first central portion therebetween, overlying the gate insulating layer; and
forming a gate electrode, overlying the central portion of the dielectric layer; and
performing an HPA process on the low temperature poly-silicon thin film transistor.

14. The method as claimed in claim 13, further comprising:
forming a passivation layer overlying the gate electrode, with a third extended portion, a second central portion covering the gate electrode and a fourth extended portion, wherein the third and fourth extended portions are in contact with the gate insulating layer.
